(19) United States
(12) Patent Application Publication
(10) Pub. No.: US 2025/0229379 A1
(43) Pub. Date: Jul. 17, 2025

(54) HIGH-PRECISION SUBSTRATE POLISHING SYSTEM

(71) Applicant: KCTECH CO.,LTD., Gyeonggi-do (KR)

(72) Inventors: In Chul SHIN, Seoul (KR); Hyun O KIM, Gyeonggi-do (KR)

(73) Assignee: KCTECH CO.,LTD., Gyeonggi-do (KR)

(21) Appl. No.: 18/702,791

(22) PCT Filed: Sep. 8, 2022
(86) PCT No.: PCT/KR2022/013525

§ 371 Date: Apr. 18, 2024

(30) Foreign Application Priority Data
Dec. 20, 2021 (KR) 10-2021-0182665
Feb. 23, 2022 (KR) 10-2022-0023678

(51) Int. Cl. B24B 37/32

(52) U.S. Cl. CPC B24B 37/32

(57) ABSTRACT

A retainer ring according to one embodiment comprises: a core part formed in a ring shape and including a metal material; and an injection part formed around the core part through molding so as to surround the core part, wherein the core part may include: a core main body formed in a ring shape; and at least one through hole formed through the core main body.

### TECHNICAL FIELD

The following embodiments relate to a high precision substrate polishing system.

### BACKGROUND ART

In the manufacture of semiconductor elements, chemical mechanical polishing (CMP) operations including polishing, buffing, and cleaning are required. The semiconductor elements have a multilayer structure, and transistor elements having a diffusion region are formed in a substrate layer. In the substrate layer, connecting metal lines are patterned and electrically connected to the transistor elements forming functional elements. As is known, a patterned conductive layer is insulated from other conductive layers with an insulating material, such as silicon dioxide. As more metal layers and associated insulating layers are formed, the need to flatten the insulating material increases. Without flattening the insulating material, the manufacturing of additional metal layers becomes substantially more difficult because of the large variation in surface morphology. In addition, a metal line pattern is formed of an insulating material so that a metal CMP operation removes excess metal.

A CMP process includes a polishing process that physically wears and flattens a surface of a substrate. The polishing process is performed by physically wearing a substrate by rubbing the substrate with a polishing pad having a groove formed in the surface. In this process, a retainer ring is provided on the outside of the substrate to prevent the substrate gripped by a carrier head from being pushed outwardly.

Furthermore, since a retainer ring is worn in contact with a polishing pad during a polishing process of a substrate, the flatness of a surface becomes uneven as the polishing process progresses. Accordingly, a method has been introduced in which a retainer ring is formed of a metal part and a plastic part, and a part in which wear occurs is formed of a plastic part. However, in the case of such a structure, the plastic part may be separated from the metal part due to friction with the polishing pad.

The above description has been possessed or acquired by the inventor(s) in the course of conceiving the present disclosure and is not necessarily an art publicly known before the present application is filed.

### DISCLOSURE OF THE INVENTION

### Technical Goals

The purpose of an embodiment is to provide a retainer ring including a core part made of a metal material and an injection part surrounding the core part, and a substrate polishing apparatus including the retainer ring.

The purpose of an embodiment is to provide a retainer ring that may prevent an injection part from being separated from a core part by improving the bonding force between the core part and the injection part, and a substrate polishing apparatus including the retainer ring.

The purpose of an embodiment is to provide a retainer ring that may prevent cracks and/or warping due to a difference in shrinkage rates depending on different materials of a core part and an injection part, and a substrate polishing apparatus including the retainer ring.

### Technical Solutions

A retainer ring according to an embodiment includes a core part formed in a ring shape and including a metal material and an injection part formed around the core part through molding to surround the core part, in which the core part includes a core main body formed in a ring shape and at least one through hole formed through the core main body.

The injection part may include an injection body having a slot in a shape corresponding to the core part in the injection body such that the core part is positioned in the injection body and a pillar part formed in a shape corresponding to the at least one through hole while being inserted into the at least one through hole.

The injection body may include an upper injection body positioned on an upper side of the core part and a lower injection body positioned on a lower side of the core part.

The pillar part may connect the upper injection body to the lower injection body.

The injection body may further include an inner injection body positioned on an inner side of the core part and an outer injection body positioned on an outer side of the core part.

The inner injection body may be formed to be stepped such that a lower portion protrudes further inwardly than an upper portion.

A stepped surface of the inner injection body may be formed to be inclined downward and inwardly.

The outer injection body may be formed to be stepped such that an upper portion protrudes further outwardly than a lower portion.

An outer circumferential surface of the core main body may include a first outer circumferential surface and a second outer circumferential surface positioned relatively lower than the first outer circumferential surface and positioned to be recessed relatively inwardly compared to the first outer circumferential surface.

The at least one through hole may be formed in plurality and disposed to be spaced apart from another in a circumferential direction of the core main body.

The core part may further include a cut part formed by being cut inwardly from an outer circumferential surface of the core main body.

The cut part may be formed at a position communicating with the at least one through hole.

The cut part may prevent shape deformation due to a difference in shrinkage rates between the core part and the injection part.

The injection part may include an engineering plastic material.

The core part may further include a tab hole to connect the retainer ring to a carrier head.

A substrate polishing apparatus according to an embodiment includes the retainer ring according to claim 1 and a carrier head connected to an upper side of the retainer ring.

### Effects

A retainer ring according to an embodiment may improve the bonding force between a core part and an injection part as a through hole is formed in the core part and may prevent the injection part from being separated from the core part.

A retainer ring according to an embodiment may prevent cracks and/or warping due to a difference in shrinkage rates depending on different materials of a core part and an injection part as a cut part is formed in the core part.

A substrate polishing apparatus according to an embodiment may include the retainer ring described above.

The effects of a retainer ring and a substrate polishing apparatus including the same according to an embodiment may not be limited to the above-mentioned effects, and other unmentioned effects may be clearly understood from the following description by one of ordinary skill in the art.

### BRIEF DESCRIPTION OF DRAWINGS

FIG. 1 is a schematic diagram of a substrate polishing apparatus according to an embodiment.

FIG. 2 is a schematic cross-sectional view of a substrate carrier according to an embodiment.

FIG. 3 is a perspective view of a core part according to an embodiment.

FIG. 4 is a plan view of a core part according to an embodiment.

FIG. 5 is a cross-sectional view taken along line I-I in FIG. 4.

FIG. 6 is an upper perspective view of a retainer ring according to an embodiment.

FIG. 7 is a lower perspective view of a retainer ring according to an embodiment.

FIG. 8 is a plan view of a retainer ring according to an embodiment.

FIG. 9 is a cross-sectional view taken along line II-II in FIG. 8.

FIG. 10 is a cross-sectional view taken along line III-III in FIG. 8.

### BEST MODE FOR CARRYING OUT THE INVENTION

The present application claims the priority based on Application Publication No. 10-2021-0182665, filed on Dec. 20, 2021, and the disclosure of which is hereby incorporated by reference herein.

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one constituent element from another constituent element, and the nature, the sequences, or the orders of the constituent elements are not limited by the terms. When one component is described as being “connected”, “coupled”, or “attached” to another component, it should be understood that one component may be connected or attached directly to another component, and an intervening component may also be “connected”, “coupled”, or “attached” to the components.

The same name may be used to describe an element included in the embodiments described above and an element having a common function. Unless otherwise mentioned, the descriptions on the embodiments may be applicable to the following embodiments and thus, duplicated descriptions will be omitted for conciseness.

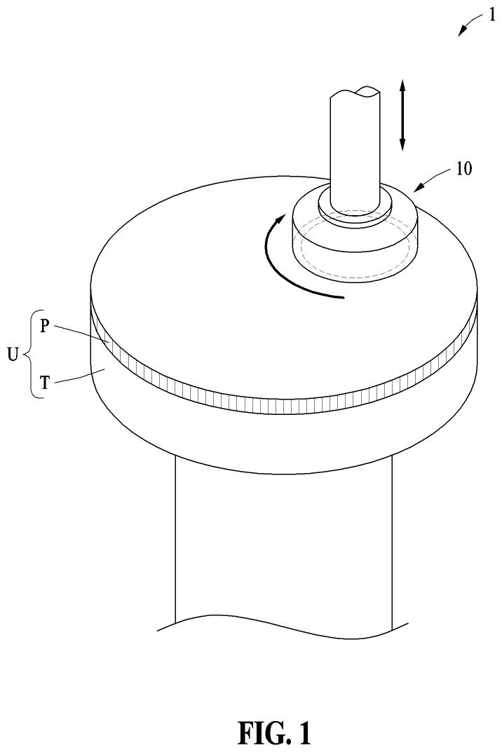

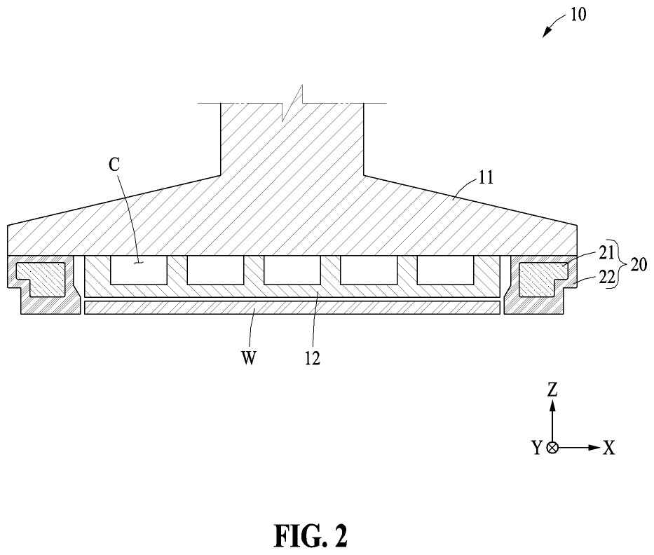

FIG. 1 is a schematic diagram of a substrate polishing apparatus according to an embodiment. FIG. 2 is a schematic cross-sectional view of a substrate carrier according to an embodiment.

Referring to FIGS. 1 and 2, a substrate polishing apparatus 1 according to an embodiment may be used for a chemical mechanical polishing (CMP) process of a substrate W.

In an embodiment, the substrate W may be a silicon wafer for manufacturing a semiconductor device. However, the type of the substrate W is not limited thereto. For example, the substrate W may include glass for flat panel display (FPD) devices, such as a liquid crystal display (LCD) or a plasma display panel (PDP).

In an embodiment, the substrate polishing apparatus 1 may polish the substrate W. The substrate polishing apparatus 1 may include a substrate carrier 10 and a polishing unit U.

In an embodiment, the polishing unit U may polish a surface to be polished of the substrate W. The polishing unit U may include a polishing table T and a polishing pad P.

In an embodiment, the polishing pad P may be connected to the polishing table T. For example, the polishing pad P may be attached to the upper portion of the polishing table T. The polishing table T may polish a surface to be polished of the substrate W in contact with the polishing pad P while rotating around an axis. The polishing table T may adjust a position of the polishing pad P with respect to the ground while moving vertically. The polishing pad P may contact the surface to be polished of the substrate W and may physically wear the surface to be polished of the substrate W. For example, the polishing pad P may include a polyurethane material.

Referring to FIG. 2, in an embodiment, the substrate carrier 10 may grip the substrate W. The substrate carrier 10 may chuck and grip the substrate W to be polished and may move the gripped substrate W to the upper portion of the polishing pad P. The substrate carrier 10 may polish the substrate W by contacting the substrate W transferred to the upper portion of the polishing pad with the polishing pad P. By pressing the substrate W in contact with the polishing pad P, the substrate carrier 10 may determine the degree of polishing of the substrate W by adjusting the frictional force between the substrate W and the polishing pad P. The substrate carrier 10 may include a carrier head 11, a membrane 12, and a retainer ring 20.

In an embodiment, the carrier head 11 may adjust a position of the substrate W. The carrier head 11 may receive power from the outside and may rotate around an axis that is perpendicular to a surface of the polishing pad P. As the carrier head 11 rotates, the gripped substrate W may be polished while rotating in contact with the polishing pad P.

In an embodiment, the carrier head 11 may move the substrate W horizontally. For example, the carrier head 11 may translate in a first direction that is parallel to a surface of the polishing pad P and a second direction that is perpendicular to the first direction. Through complex movement in the first direction and the second direction, the carrier head 11 may move the substrate W on a plane that is parallel to the surface of the polishing pad P. As a result, the substrate W may be transferred to or removed from a polishing position according to the horizontal movement of the carrier head 11.

In an embodiment, the carrier head 11 may move the substrate W vertically with respect to the ground. The carrier head 11 may move vertically with respect to a support of the substrate W for chucking/dechucking the substrate W or may move vertically with respect to the polishing pad P for polishing the substrate W.

In an embodiment, the membrane 12 may be connected to the carrier head 11 and may form a pressure chamber C to apply pressure to the substrate W. The pressure acting on the substrate W may be adjusted according to a pressure change in the pressure chamber C formed by the membrane 12. For example, the degree to which the substrate W is pressed against the polishing pad P may increase through the pressure rise of the pressure chamber C while the substrate W contacts the polishing pad P. The membrane 12 may include a bottom plate forming the bottom surface of the pressure chamber C and a flap forming the side wall of the pressure chamber C. The flap may be formed in plurality to have different radii based on the center of the bottom plate, and each pressure chamber C may be formed for each space between adjacent flaps. Different pressures may be applied to the pressure chamber C, and a portion of the substrate W corresponding to each pressure chamber C may be locally pressed according to the pressure applied to each pressure chamber C.

In an embodiment, the retainer ring 20 may be connected to the carrier head 11 to surround the circumference of the gripped substrate W. The retainer ring 20 may prevent the substrate W from being separated from a position in which the substrate W is gripped. For example, the retainer ring 20 may support the side surface of the substrate W to prevent the substrate W from being separated from the substrate carrier 10 due to vibration and/or friction occurring during the polishing process of the substrate W.

In an embodiment, the retainer ring 20 may be directly connected to the carrier head 11 or may be indirectly connected to the carrier head 11 through a separate fastening member. For example, the retainer ring 20 may be connected to the lower side (e.g., the side in the −z direction) of the carrier head 11 through a fastening member (e.g., a bolt, etc.). The retainer ring 20 may include a core part 21 and an injection part 22.

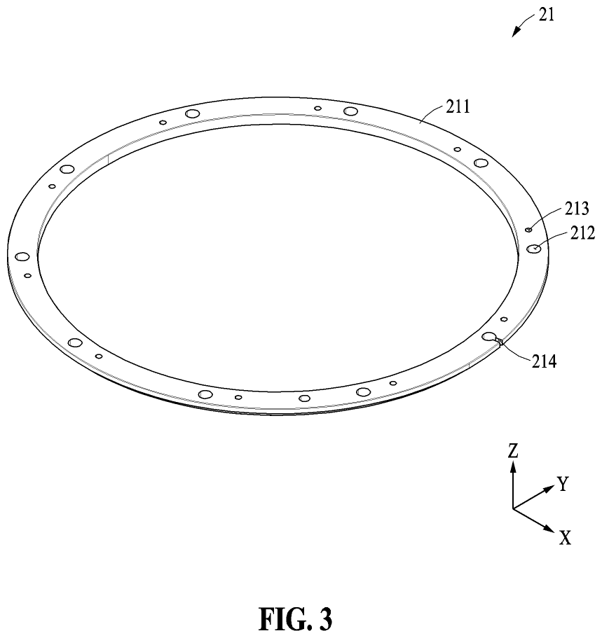

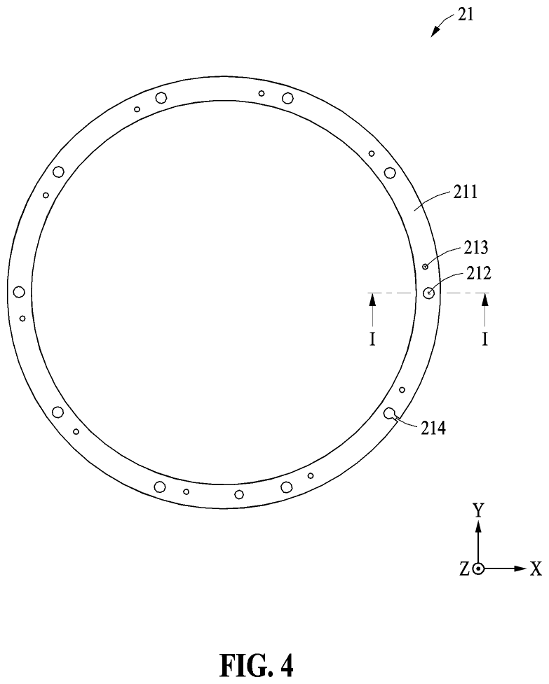

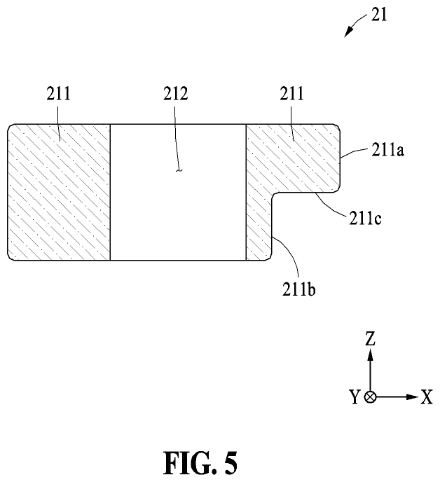

FIG. 3 is a perspective view of a core part according to an embodiment. FIG. 4 is a plan view of a core part according to an embodiment. FIG. 5 is a cross-sectional view taken along line I-I in FIG. 4.

Referring to FIGS. 3 to 5, in an embodiment, the core part 21 may be formed in a ring shape. The core part 21 may be substantially positioned inside a retainer ring (e.g., the retainer ring 20 of FIG. 2). The core part 21 may include a metal material. For example, the core part 21 may include a stainless-steel material.

In an embodiment, the core part 21 may include a core main body 211, a through hole 212, a cut part 213, and a tab hole 214.

In an embodiment, the core main body 211 may form the exterior of the core part 21. The core main body 211 may be formed in a ring shape. The through hole 212, the cut part 213, and the tab hole 214, which are described below, may be formed in the core main body 211.

In an embodiment, the outer circumferential surface (e.g., the surface in the +x direction based on FIG. 5) of the core main body 211 may be formed to be stepped. For example, the outer circumferential surface of the core main body 211 may include a first outer circumferential surface 211a, a second outer circumferential surface 211b, and a stepped surface 211c. The first outer circumferential surface 211a may be positioned substantially in the upper side (e.g., the side in the +z direction) of the core main body 211 and the second outer circumferential surface 211b may be positioned substantially in the lower side (e.g., the side in the −z direction) of the core main body 211. That is, the second outer circumferential surface 211b may be positioned on a relatively lower side (e.g., the side in the −z direction) than the first outer circumferential surface 211a. The second outer circumferential surface 211b may be positioned to be recessed relatively inwardly (e.g., the −x direction based on FIG. 5) compared to the first outer circumferential surface 211a. For example, based on FIG. 5, the second outer circumferential surface 211b may be positioned to be recessed in the −x direction compared to the first outer circumferential surface 211a. The stepped surface 211c connecting the first outer circumferential surface 211a to the second outer circumferential surface 211b may be formed in the substantially horizontal direction (e.g., the x direction).

In an embodiment, the through hole 212 may be formed through the core main body 211. For example, the through hole 212 may be formed through the core main body 211 in the vertical direction (e.g., the z direction). The through hole 212 may be formed in a substantially cylindrical shape. However, this is only an example, and the shape of the through hole 212 is not limited thereto.

In an embodiment, at least one through hole 212 may be formed. For example, the through hole 212 may be formed in plurality, and the plurality of through holes 212 may be disposed to be spaced apart from each other in the circumferential direction of the core main body 211. The plurality of through holes 212 may be formed to have substantially the same size. Alternatively, some of the plurality of through holes 212 may be formed to have different sizes. However, this is only an example, and the number and/or size of the through holes 212 are not limited thereto.

In an embodiment, the cut part 213 may be formed by being cut inwardly (e.g., the inner side in the diameter direction) from the outer circumferential surface (e.g., the surface positioned on the outer side in the diameter direction) of the core main body 211. The cut part 213 may be formed at a position communicating with the through hole 212. For example, the cut part 213 may be formed by being cut in the inner side direction (e.g., the inner side in the diameter direction) from the outer end portion (e.g., the outer end portion in the diameter direction) of the core main body 211 to a position communicating with the through hole 212 by a predetermined width. The cut part 213 may be formed as one cut part 213 or a plurality of cut parts 213. However, this is only an example, and the number and/or shape of the cut parts 213 are not limited thereto. The cut part 213 may prevent shape deformation due to a difference in shrinkage rates between the core part 21 and the injection part 22.

In an embodiment, the tab hole 214 may be formed through the core main body 211. For example, the tab hole 214 may be formed through the core main body 211 in the vertical direction (e.g., the z direction). The tab hole 214 may be formed in a substantially cylindrical shape. However, this is only an example, and the shape of the tab hole 214 is not limited thereto.

In an embodiment, at least one tab hole 214 may be formed. For example, the tab hole 214 may be formed in plurality, and the plurality of tab holes 214 may be disposed to be spaced apart from each other in the circumferential direction of the core main body 211. The tab hole 214 may be formed to have a smaller size than that of the through hole 212. The tab holes 214 and the through holes 212 may be formed in numbers corresponding to each other. For example, the tab hole 214 may be formed adjacent to the through hole 212. The tab hole 214 and the through hole 212 may be alternately positioned in the circumferential direction of the core main body 211. However, this is only an example, and the number and/or size of the tab holes 214 are not limited thereto.

In an embodiment, the tab hole 214 may be a hole for connecting a retainer ring (e.g., the retainer ring 20 of FIG. 2) to a carrier head (e.g., the carrier head 11 of FIG. 2). For example, the retainer ring 20 may be fastened to the carrier head 11 as a fastening member (e.g., a bolt, etc.) is inserted into the tab hole 214. For example, threads may be formed in the inner circumferential surface of the tab hole 214.

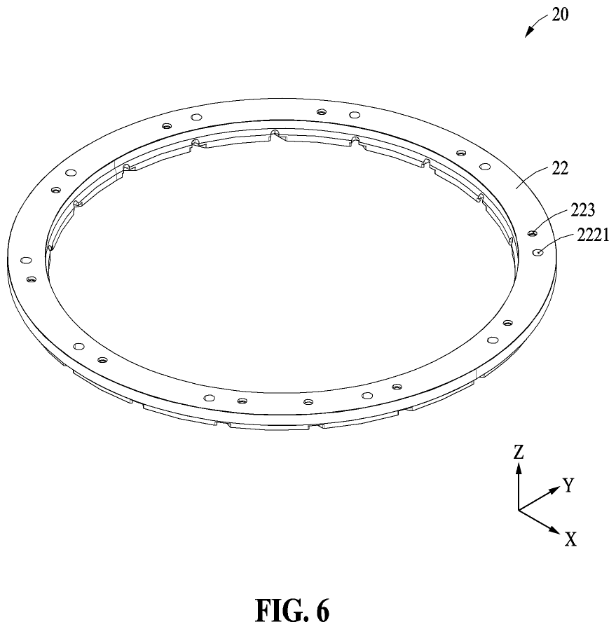

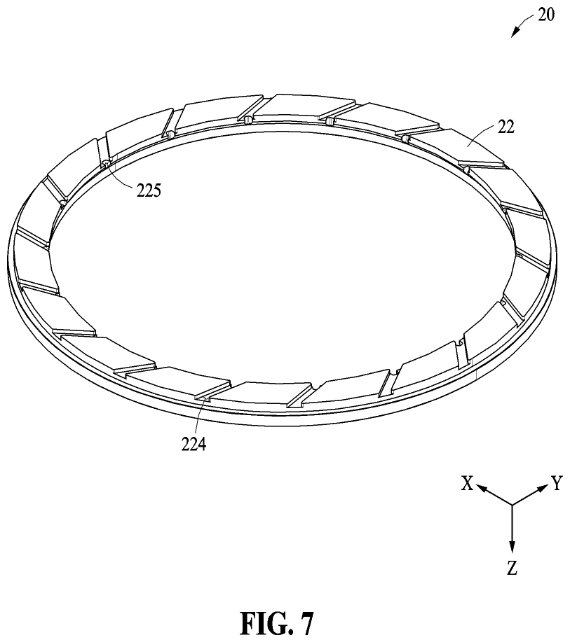

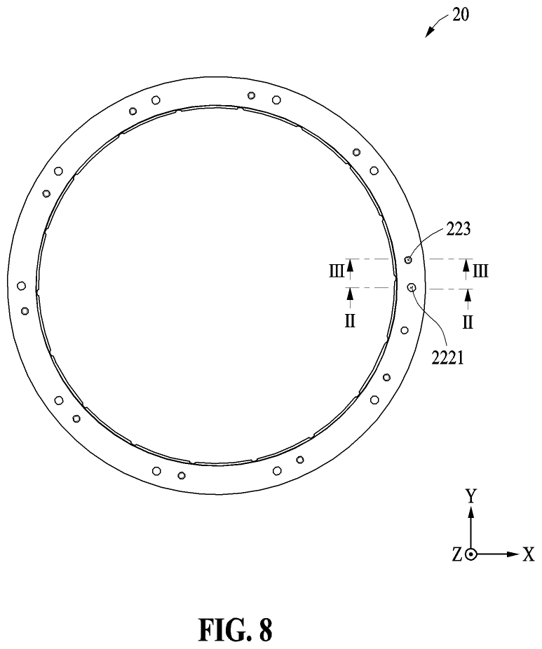

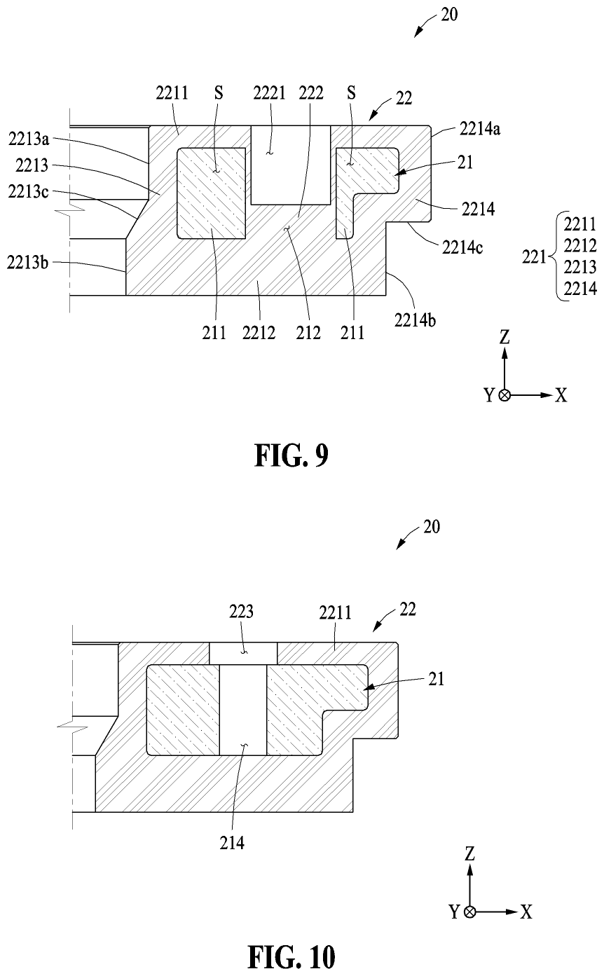

FIG. 6 is an upper perspective view of a retainer ring according to an embodiment. FIG. 7 is a lower perspective view of a retainer ring according to an embodiment. FIG. 8 is a plan view of a retainer ring according to an embodiment. FIG. 9 is a cross-sectional view taken along line II-II in FIG. 8. FIG. 10 is a cross-sectional view taken along line III-III in FIG. 8.

Referring to FIGS. 3 to 10, in an embodiment, the injection part 22 may be formed to surround the core part 21. The injection part 22 may be formed around the core part 21 through molding. For example, the injection part 22 may be formed by being molded into the entire surface of the core part 21. For example, the injection part 22 may be formed by the entire molding method in the mold frame of the fixed core part 21. The injection part 22 may be substantially bonded to the core part 21 through injection.

In an embodiment, the injection part 22 may be made of a different material from that of the core part 21. For example, the injection part 22 may include an engineering plastic material. For example, the injection part 22 may include polyether ether ketone (PEEK). Since the core part 21 and the injection part 22 are made of different materials, the core part 21 and the injection part 22 may have different shrinkage rates. In this way, when the core part 21 and the injection part 22 have different shrinkage rates, cracks and/or warping may occur in the core part 21 and/or the injection part 22 in the process of cooling an injection member after injection but such cracks and/or warping may be prevented by the cut part 213 formed in the core part 21. For example, a space formed by the cut part 213 may act as a buffer space where contraction or expansion may occur during the cooling process, and accordingly, cracks and/or warping may be prevented even when the shrinkage rates of the core part 21 and the injection part 22 are different.

In an embodiment, the injection part 22 may include an injection body 221, a pillar part 222, an upper tab hole 223, a bottom groove 224, and an inner circumferential through hole 225.

In an embodiment, the injection body 221 may have a slot S in the injection body such that the core part 21 is positioned in the injection body 221. The slot S may be formed in a shape substantially corresponding to the core part 21. The core part 21 may be positioned in the slot S, and the injection body 221 may surround the core part 21 in all directions. For example, the injection body 221 may be a part formed by being injected into the outer side surface of the core part 21.

In an embodiment, the injection body 221 may include an upper injection body 2211, a lower injection body 2212, an inner injection body 2213, and an outer injection body 2214.

In an embodiment, the upper injection body 2211 may be a part positioned on the upper side (e.g., the +z direction) of the core part 21. The upper injection body 2211 may be a part formed by substantially being injected into the upper surface (e.g., the surface in the +z direction) of the core part 21. That is, the upper injection body 2211 may form a part of the upper side (e.g., the +z direction) of the injection body 221. For example, the upper injection body 2211 may be positioned to contact the upper surface (e.g., the surface in the +z direction) of the core part 21.

In an embodiment, the lower injection body 2212 may be a part positioned on the lower side (e.g., the −z direction) of the core part 21. The lower injection body 2212 may be a part formed by substantially being injected into the lower surface (e.g., the surface in the −z direction) of the core part 21. That is, the lower injection body 2212 may form a part of the lower side (e.g., the −z direction) of the injection body 221. For example, the lower injection body 2212 may be positioned to contact the lower surface (e.g., the surface in the −z direction) of the core part 21.

In an embodiment, the inner injection body 2213 may be a part positioned on the inner side (e.g., the −x direction based on FIG. 9) of the core part 21. The inner injection body 2213 may be a part formed by substantially being injected into the inner circumferential surface of the core part 21. That is, the inner injection body 2213 may form the inner circumferential portion of the injection body 221. For example, the inner injection body 2213 may be positioned to contact the inner circumferential surface of the core part 21.

In an embodiment, the inner injection body 2213 may be formed to be stepped such that the lower portion (e.g., the portion in the −z direction) protrudes further inwardly (e.g., the −x direction based on FIG. 9) than the upper portion (e.g., the portion in the +z direction). For example, the inner circumferential surface of the inner injection body 2213 may include an upper inner circumferential surface 2213a, a lower inner circumferential surface 2213b, and an inner stepped surface 2213c. The lower inner circumferential surface 2213b may be formed at a position protruding further inwardly (e.g., the −x direction based on FIG. 9) than the upper inner circumferential surface 2213a. The inner stepped surface 2213c may be formed to be inclined downward (e.g., the −z direction) and inwardly (e.g., the −x direction based on FIG. 9). However, this is only an example, and the shape of the inner injection body 2213 is not limited thereto.

In an embodiment, the outer injection body 2214 may be a part positioned on the outer side (e.g., the +x direction based on FIG. 9) of the core part 21. The outer injection body 2214 may be a part formed by substantially being injected into the outer circumferential surface of the core part 21. That is, the outer injection body 2214 may form the outer circumferential portion of the injection body 221. For example, the outer injection body 2214 may be positioned to contact the outer circumferential surface of the core part 21. In an embodiment, the outer injection body 2214 may be formed to be stepped such that the upper portion (e.g., the portion in the +z direction) protrudes further outwardly (e.g., the +x direction based on FIG. 9) than the lower portion (e.g., the portion in the −z direction). For example, the outer circumferential surface of the outer injection body 2214 may include an upper outer circumferential surface 2214a, a lower outer circumferential surface 2214b, and an outer stepped surface 2214c. The upper outer circumferential surface 2214a may be formed at a position protruding further outwardly (e.g., the +x direction based on FIG. 9) than the lower outer circumferential surface 2214b. The outer stepped surface 2214c may be formed in the substantially horizontal direction (e.g., the x direction). However, this is only an example, and the shape of the outer injection body 2214 is not limited thereto.

In an embodiment, the pillar part 222 may be formed in a shape substantially corresponding to the through hole 212 while being inserted into the through hole 212. For example, the pillar part 222 may be a part formed by being injected into the through hole 212. The pillar part 222 may be formed at a position corresponding to the through hole 212. The pillar part 222 may cross the slot S to substantially connect the upper injection body 2211 to the lower injection body 2212. According to this structure, since the injection part 22 penetrates the core part 21 through the pillar part 222, the bonding force between the injection part 22 and the core part 21 may be improved. Accordingly, it may be possible to prevent the injection part 22 from being separated from the core part 21 even due to vibration and/or friction during the polishing process. Furthermore, the pillar part 222 may also include a recessed part 2221 that is recessed from the upper surface (e.g., the surface in the +z direction) of the upper pillar part 222 toward the lower side (e.g., the −z direction).

In an embodiment, the upper tab hole 223 may be formed at a position communicating with the tab hole 214 of the core part 21. The upper tab hole 223 may be formed through the upper injection body 2211 of the injection part 22 to communicate with the tab hole 214 of the core part 21. For example, the upper tab hole 223 may be formed to have a larger cross-section than that of the tab hole 214 of the core part 21. A fastening member (e.g., a bolt, etc.) for connecting the retainer ring 20 to a carrier head (e.g., the carrier head 11 of FIG. 2) may be inserted into the upper tab hole 223 and the 20) tab hole 214. However, this is only an example, and the shape of the upper tab hole 223 is not limited thereto.

In an embodiment, the bottom groove 224 may be formed in the lower portion (e.g., the portion in the −z direction) of the injection part 22. For example, the bottom groove 224 may be formed by being recessed from the lower surface (e.g., the surface in the +z direction) of the lower injection body 2212 to the upper side (e.g., the −z direction). The bottom groove 224 may be formed to extend from the inner circumferential surface of the injection part 22 to the outer circumferential surface to penetrate the injection part 22 in the diameter direction. The bottom groove 224 may be formed to be inclined with respect to the diameter direction. However, this is only an example, and the bottom 30 groove 224 may be formed parallel to the diameter direction. The bottom groove 224 may be formed in plurality. The plurality of bottom grooves 224 may be formed to be spaced apart from each other in the circumferential direction of the injection part 22. The bottom groove 224 may function as a passage for discharging slurry and/or particles in the internal space formed by the retainer ring 20 to the outside of the retainer ring 20.

In an embodiment, the inner circumferential through hole 225 may be formed through the inner circumferential side of the injection part 22 from the lower side (e.g., the side in the −z direction). For example, the inner circumferential through hole 225 may be formed through the inner injection body 2213 from the lower surface (e.g., the surface in the −z direction) of the inner injection body 2213 to the upper direction (e.g., the +z direction). The inner circumferential through hole 225 may be formed at a position communicating with the bottom groove 224. The inner circumferential through hole 225 may be formed to have a width that is less than that of the bottom groove 224. For example, the inner circumferential through hole 225 may be formed in a cylindrical shape. However, this is only an example, and the shape of the inner circumferential through hole 225 is not limited thereto.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

1. A retainer ring comprising:
a core part formed in a ring shape and comprising a metal material; and
an injection part formed around the core part through molding to surround the core part,
wherein the core part comprises:
a core main body formed in a ring shape; and
at least one through hole formed through the core main body.

2. The retainer ring of claim 1, wherein the injection part comprises:
an injection body having a slot in a shape corresponding to the core part in the injection body such that the core part is positioned in the injection body; and
a pillar part formed in a shape corresponding to the through hole while being inserted into the through hole.

3. The retainer ring of claim 2, wherein the injection body comprises:
an upper injection body positioned on an upper side of the core part; and
a lower injection body positioned on a lower side of the core part.

4. The retainer ring of claim 3, wherein the pillar part connects the upper injection body to the lower injection body.

5. The retainer ring of claim 3, wherein the injection body further comprises:
an inner injection body positioned on an inner side of the core part; and
an outer injection body positioned on an outer side of the core part.

6. The retainer ring of claim 5, wherein the inner injection body is formed to be stepped such that a lower portion protrudes further inwardly than an upper portion.

7. The retainer ring of claim 6, wherein a stepped surface of the inner injection body is formed to be inclined downward and inwardly.

8. The retainer ring of claim 5, wherein the outer injection body is formed to be stepped such that an upper portion protrudes further outwardly than a lower portion.

9. The retainer ring of claim 1, wherein an outer circumferential surface of the core main body comprises:
a first outer circumferential surface; and
a second outer circumferential surface positioned relatively lower than the first outer circumferential surface and positioned to be recessed relatively inwardly compared to the first outer circumferential surface.

10. The retainer ring of claim 1, wherein the through hole is formed in plurality and disposed to be spaced apart from another in a circumferential direction of the core main body.

11. The retainer ring of claim 1, wherein the core part further comprises a cut part formed by being cut inwardly from an outer circumferential surface of the core main body.

12. The retainer ring of claim 11, wherein the cut part is formed at a position communicating with the through hole.

13. The retainer ring of claim 12, wherein the cut part prevents shape deformation due to a difference in shrinkage rates between the core part and the injection part.

14. The retainer ring of claim 1, wherein the injection part comprises an engineering plastic material.

15. The retainer ring of claim 1, wherein the core part further comprises a tab hole to connect the retainer ring to a carrier head.

16. A substrate polishing apparatus comprising:
the retainer ring according to claim 1; and
a carrier head connected to an upper side of the retainer ring.
